(19) United States
(12) Patent Application Publication
(10) Pub. No.: US 2026/0231770 A1
(43) Pub. Date: Aug. 6, 2026

(54) SEMICONDUCTOR PACKAGE STRUCTURE AND METHOD FOR FORMING THE SAME

(71) Applicant: Taiwan Semiconductor Manufacturing Company, Ltd., Hsinchu (TW)

(72) Inventors: Tzuan-Horng LIU, Taoyuan City (TW); An-Jhih SU, Taoyuan City (TW)

(73) Assignee: Taiwan Semiconductor Manufacturing Company, Ltd., Hsinchu (TW)

(21) Appl. No.: 19/047,094

(22) Filed: Feb. 6, 2025

(51) Int. Cl. H01L 23/58; H01L 23/00; H01L 23/31; H01L 23/538; H01L 25/00; H01L 25/11

(52) U.S. Cl. CPC H10W 42/00; H10W 70/611; H10W 70/65; H10W 90/00; H10W 74/114; H10W 90/22

(57) ABSTRACT

A semiconductor package structure is provided, which includes an interconnect structure, a first molding layer disposed over the interconnect structure, a first semiconductor die disposed in the first molding layer, a redistribution layer disposed over the first molding layer, and a first sealing structure extending from the interconnect structure through the first molding layer to the redistribution layer. The first semiconductor die is surrounded by the first sealing structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a semiconductor device, in accordance with some embodiments of the present disclosure.

FIG. 2A to FIG. 2D are schematic views showing the process of forming a semiconductor device, in accordance with some embodiments of the present disclosure.

FIG. 3A to FIG. 3E are schematic views showing the process of forming a semiconductor device, in accordance with some embodiments of the present disclosure.

FIG. 4A to FIG. 4F are schematic views showing the process of forming a semiconductor package structure, in accordance with some embodiments of the present disclosure.

FIG. 5 is a cross-sectional view of a semiconductor package structure, in accordance with some embodiments of the present disclosure.

FIG. 6A, FIG. 6B, FIG. 6C, and FIG. 6D are top views of semiconductor package structures, in accordance with some embodiments of the present disclosure.

FIG. 7A is a cross-sectional view of a semiconductor package structure, in accordance with some embodiments of the present disclosure.

FIG. 7B is a cross-sectional view of a semiconductor package structure, in accordance with some embodiments of the present disclosure.

FIG. 7C is a cross-sectional view of a semiconductor package structure, in accordance with some embodiments of the present disclosure.

FIG. 7D is a cross-sectional view of a semiconductor package structure, in accordance with some embodiments of the present disclosure.

FIG. 8A, FIG. 8B, FIG. 8C, FIG. 8D, and FIG. 8E are top views of semiconductor package structures, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

The terms “about” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

A semiconductor package structure is provided in some embodiments of the present disclosure. For example, the semiconductor package structure may be a system-on-panel (SoP) package having a seal ring surrounding dies in the package, and the seal ring may continuously extend from a frontside redistribution layer (RDL) to a backside RDL to enhance the structural strength and reliability of the semiconductor package structure.

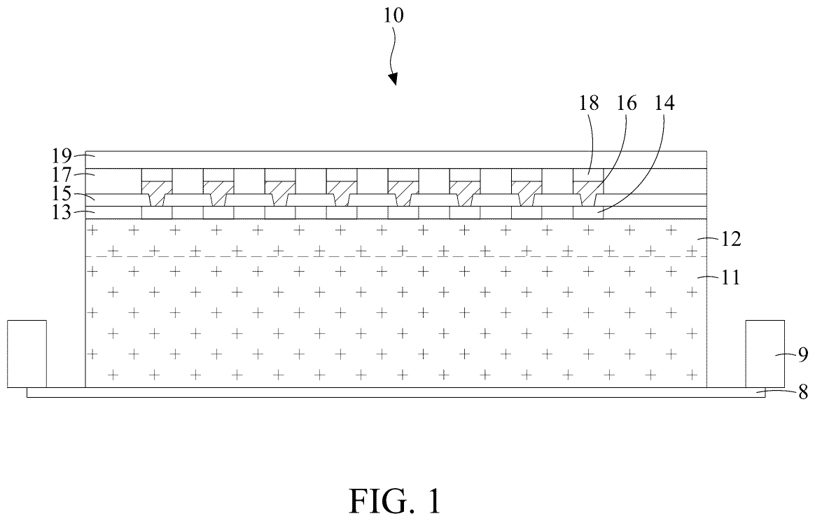

FIG. 1 is a schematic view of a semiconductor device 10, in accordance with some embodiments of the present disclosure. As shown in FIG. 1, the semiconductor device 10 includes a substrate 11, a device layer 12 disposed in the substrate 11, a passivation layer 13 disposed over the substrate 11, conductive pads 14 disposed in the passivation layer 13, a dielectric layer 15 disposed on the passivation layer 13, a dielectric layer 17 disposed on the dielectric layer 15, conductive features 16 and 18 disposed in the dielectric layers 15 and 17, and an organic layer 19 disposed over the dielectric layer 17, in accordance with some embodiments.

In some embodiments, the substrate 11 may be made of silicon (Si) or other semiconductor materials, such as germanium (Ge) or silicon germanium (SiGe). In some embodiments, the substrate 11 may include a compound semiconductor, such as silicon carbide (SiC), silicon phosphide (SiP), gallium arsenide (GaAs), gallium phosphide (GaP), indium phosphide (InP), indium arsenide (InAs), indium antimonide (InSb), zinc oxide (ZnO), zinc selenide (ZnSe), zinc sulfide (ZnS), zinc telluride (ZnTe), cadmium selenide (CdSe), cadmium sulfide (CdS), and/or cadmium telluride (CdTe); an alloy semiconductor, such as silicon germanium (SiGe), silicon phosphorus carbide (SiPC), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); other group III-V materials; other group II-V materials; or combinations thereof. In some embodiments, the substrate 11 may be a glass substrate or any other substrate material.

In some embodiments, the device layer 12 are formed on the substrate 11 during the front-end-of-line (FEOL) processes. Various microelectronic components may be formed in or on the device layer 12. In some embodiments, the various microelectronic components may include transistor components such as source/drain features, gate structures, gate spacers, source/drain contacts, gate contacts, isolation structures including shallow trench isolation (STI), or any other suitable components. Transistor components formed on the device layer 12 may include multi-gate devices, such as fin-type field effect transistors (FinFETs), multi-bridge-channel (MBC) transistors, or other FETs with nanostructures. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. Depending on the shape of the channel member that may resemble a wire or a sheet, an MBC transistor may also be referred to as nanowire transistors or nanosheet transistors.

In some embodiments, the passivation layer 13 may include polymers such as polybenzoxazole (PBO), polyimide, benzocyclobutene (BCB,) or the like. Alternatively, the passivation layer 13 may include non-organic dielectric materials such as silicon oxide, silicon nitride, silicon carbide, silicon oxynitride, or the like. The passivation layer 13 may be deposited by, for example, chemical vapor deposition (CVD), physical vapor deposition (PVD), atomic layer deposition (ALD), or the like.

In some embodiments, the dielectric layers 15 and 17 are formed using a deposition method such as plasma-enhanced chemical vapor deposition (PECVD), low-pressure chemical vapor deposition (LPCVD), or the like. In some embodiments, the dielectric layers 15 and 17 may be made of a polymer material such as epoxy, polyimide, polybenzoxazole (PBO), benzocyclobutene (BCB), solder resist (SR), ABF film, and the like, in accordance with some embodiments. In some embodiments, the dielectric layers 15 and 17 are made of a photosensitive material and may undergo chemical reactions when exposed to light. In some embodiments, the dielectric layers 15 and 17 may include phospho-silicate glass (PSG), boro-silicate glass (BSG), boron-doped phospho-silicate glass (BPSG), undoped silicate glass (USG), or the like. In some embodiments of the present disclosure, the dielectric layers 15 and 17 may include an inorganic dielectric material, which may include a material selected from silicon nitride (SiNₓ), silicon oxide (SiO₂), silicon oxy-nitride (SiONₓ), silicon oxy-carbide (SiOCₓ), silicon carbide (SiC), combinations or multiple layers thereof, or the like.

In some embodiments, conductive features 16 and 18 may include conductive wires, vias, pillars, pads, etc. The conductive pad 14 and the conductive features 16 and 18 may be formed by a deposition method, such as chemical vapor deposition (CVD), physical vapor deposition (PVD), or atomic layer deposition (ALD), following by a patterning process. The conductive pad 14 and the conductive features 16 and 18 may include Tungsten (W), aluminum (Al), copper (Cu), titanium (Ti), tantalum (Ta), titanium nitride (TiN), tantalum nitride (TaN), alloys or multiple layers thereof, or the like, in accordance with some embodiments.

In some embodiments, the organic layer 19 is formed using a deposition method such as plasma-enhanced chemical vapor deposition (PECVD), low-pressure chemical vapor deposition (LPCVD), or the like. In some embodiments, the organic layer 19 is formed by spin coating. In some embodiments, the organic layer 19 may be made of a polymer material such as epoxy, polyimide, polybenzoxazole (PBO), benzocyclobutene (BCB), solder resist (SR), ABF film, and the like, in accordance with some embodiments.

In some embodiments, the semiconductor device 10 is placed over a tape layer 8 having a frame 9 for subsequent processes. The tape layer 8 is made of a polymer material or another suitable material, in accordance with some embodiments. In some embodiments, the tape layer 8 include photosensitive or heat-sensitive material and is easily detached from the semiconductor device 10.

In some embodiments, the frame 9 protects the semiconductor device 10 from damage during transportation and handling, such as scratches and contamination. Furthermore, the frame 9 provides a stable platform for inspection and testing, and enables the accurate alignment of the semiconductor device 10 during subsequent processes. In some embodiments, the frame 9 includes rigid material provide mechanical support.

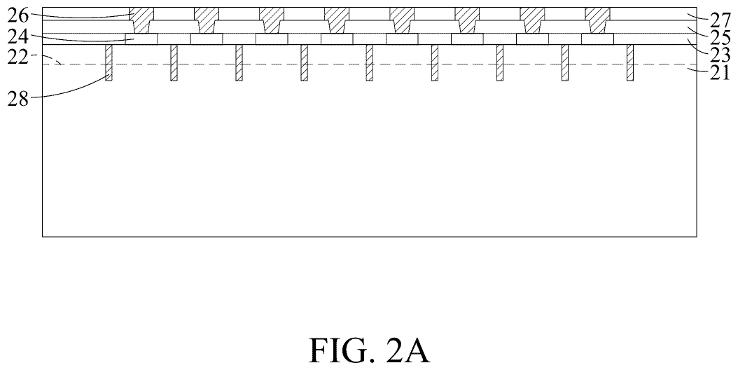

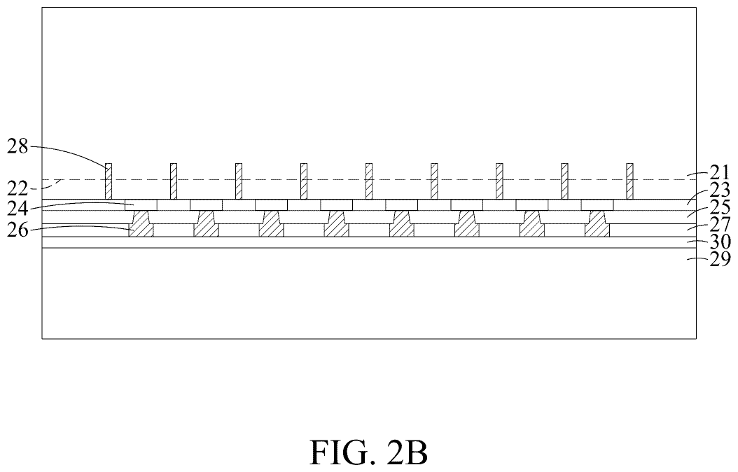

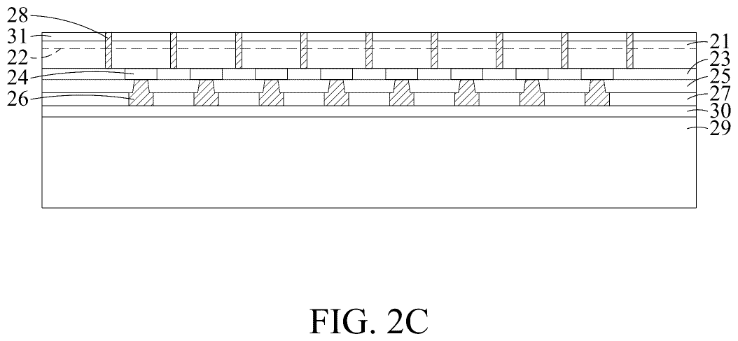

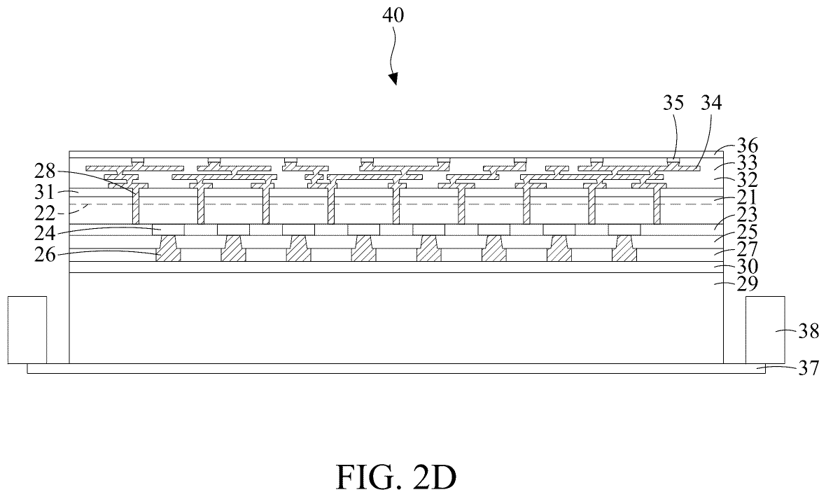

FIG. 2A to FIG. 2D are schematic views showing the process of forming a semiconductor device 40, in accordance with some embodiments of the present disclosure. As shown in FIG. 2A, a substrate 21 is provided. In some embodiments, the substrate 21 may be made of silicon (Si) or other semiconductor materials, such as germanium (Ge) or silicon germanium (SiGe). In some embodiments, the substrate 21 may include a compound semiconductor, such as silicon carbide (SiC), silicon phosphide (SiP), gallium arsenide (GaAs), gallium phosphide (GaP), indium phosphide (InP), indium arsenide (InAs), indium antimonide (InSb), zinc oxide (ZnO), zinc selenide (ZnSe), zinc sulfide (ZnS), zinc telluride (ZnTe), cadmium selenide (CdSe), cadmium sulfide (CdS), and/or cadmium telluride (CdTe); an alloy semiconductor, such as silicon germanium (SiGe), silicon phosphorus carbide (SiPC), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); other group III-V materials; other group II-V materials; or combinations thereof. In some embodiments, the substrate 21 may be a glass substrate or any other substrate material.

In some embodiments, a device layer 22 is formed on the substrate 21 during the front-end-of-line (FEOL) processes. Various microelectronic components may be formed in or on the device layer 22. In some embodiments, the various microelectronic components may include transistor components such as source/drain features, gate structures, gate spacers, source/drain contacts, gate contacts, isolation structures including shallow trench isolation (STI), or any other suitable components. Transistor components formed on the device layer 22 may include multi-gate devices, such as fin-type field effect transistors (FinFETs), multi-bridge-channel (MBC) transistors, or other FETs with nanostructures. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. Depending on the shape of the channel member that may resemble a wire or a sheet, an MBC transistor may also be referred to as nanowire transistors or nanosheet transistors.

In some embodiments, a passivation layer 23 is formed over the substrate 21 and may include polymers such as polybenzoxazole (PBO), polyimide, benzocyclobutene (BCB), or the like. Alternatively, the passivation layer 23 may include non-organic dielectric materials such as silicon oxide, silicon nitride, silicon carbide, silicon oxynitride, or the like. The passivation layer 23 may be deposited by, for example, chemical vapor deposition (CVD), physical vapor deposition (PVD), atomic layer deposition (ALD), or the like.

In some embodiments, dielectric layers 25 and 27 are over the passivation layer 23 formed using a deposition method such as plasma-enhanced chemical vapor deposition (PECVD), low-pressure chemical vapor deposition (LPCVD), or the like. In some embodiments, the dielectric layers 25 and 27 may be made of a polymer material such as epoxy, polyimide, polybenzoxazole (PBO), benzocyclobutene (BCB), solder resist (SR), ABF film, and the like, in accordance with some embodiments. In some embodiments, the dielectric layers 25 and 27 are made of a photosensitive material and may undergo chemical reactions when exposed to light. In some embodiments, the dielectric layers 25 and 27 may include phospho-silicate glass (PSG), boro-silicate glass (BSG), boron-doped phospho-silicate glass (BPSG), undoped silicate glass (USG), or the like. In some embodiments of the present disclosure, the dielectric layers 25 and 27 may include an inorganic dielectric material, which may include a material selected from silicon nitride (SiNₓ), silicon oxide (SiO₂), silicon oxy-nitride (SiONₓ), silicon oxy-carbide (SiOCₓ), silicon carbide (SiC), combinations or multiple layers thereof, or the like.

In some embodiments, conductive pads 24 may be formed in the passivation layer 23. In some embodiments, conductive features 26 may be formed in the dielectric layers 25 and 27, and the conductive features 26 include conductive wires, vias, pillars, pads, etc. In some embodiments, conductive features 28 may include conductive feature and may be formed in the substrate 21 and connects to the device layer 22 to provide electrical connection to the components in the device layer 22. In some embodiments, the conductive pad 24 and the conductive features 26 and 28 may be formed by a deposition method, such as chemical vapor deposition (CVD), physical vapor deposition (PVD), or atomic layer deposition (ALD), following by a patterning process. The conductive pad 24 and the conductive features 26 and 28 may include Tungsten (W), aluminum (Al), copper (Cu), titanium (Ti), tantalum (Ta), titanium nitride (TiN), tantalum nitride (TaN), alloys or multiple layers thereof, or the like.

In FIG. 2B, the structure in FIG. 2A is flipped over and disposed on a carrier 29 having a release layer 30. The carrier 29 may be made of silicon (Si) or other semiconductor materials, such as germanium (Ge) or silicon germanium (SiGe). In some embodiments, the carrier 29 may include a compound semiconductor, such as silicon carbide (SiC), silicon phosphide (SiP), gallium arsenide (GaAs), gallium phosphide (GaP), indium phosphide (InP), indium arsenide (InAs), indium antimonide (InSb), zinc oxide (ZnO), zinc selenide (ZnSe), zinc sulfide (ZnS), zinc telluride (ZnTe), cadmium selenide (CdSe), cadmium sulfide (CdS), and/or cadmium telluride (CdTe); an alloy semiconductor, such as silicon germanium (SiGe), silicon phosphorus carbide (SiPC), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); other group III-V materials; other group II-V materials; or combinations thereof. In some embodiments, the carrier 29 may be a glass substrate or any other substrate material.

In some embodiments, the release layer 30 may be formed of a polymer-based material and/or an epoxy-based thermal-release material (such as a Light-To-Heat-Conversion (LTHC) material), which is capable of being decomposed under radiation such as a laser beam, so that the carrier 29 may be de-bonded from the overlying structures that will be formed in subsequent processes. In accordance with some embodiments of the present disclosure, the release layer 30 is applied on the carrier 29 through coating.

As shown in FIG. 2C, the substrate 21 is thinned to expose the conductive feature 28. The thinning of the substrate 21 may be effected by a planarization process, such as chemical mechanical polishing (CMP) or a mechanical grinding process, or may be effected by an isotropic etch process, and/or an anisotropic etch process, in accordance with some embodiments.

Afterwards, a dielectric layer 31 is disposed on the substrate 21. In some embodiments, the dielectric layer 31 is formed using a deposition method such as plasma-enhanced chemical vapor deposition (PECVD), low-pressure chemical vapor deposition (LPCVD), or the like. Afterwards, a planarization process, such as chemical mechanical polishing (CMP) or a mechanical grinding process, may be performed to the dielectric layer 31. In some embodiments, the dielectric layer 31 may be made of a polymer material such as epoxy, polyimide, polybenzoxazole (PBO), benzocyclobutene (BCB), solder resist (SR), ABF film, and the like, in accordance with some embodiments. In some embodiments, the dielectric layer 31 is made of a photosensitive material and may undergo chemical reactions when exposed to light. In some embodiments, the dielectric layer 31 may include phospho-silicate glass (PSG), boro-silicate glass (BSG), boron-doped phospho-silicate glass (BPSG), undoped silicate glass (USG), or the like. In some embodiments of the present disclosure, the dielectric layer 31 may include an inorganic dielectric material, which may include a material selected from silicon nitride (SiNₓ), silicon oxide (SiO₂), silicon oxy-nitride (SiONₓ), silicon oxy-carbide (SiOCₓ), silicon carbide (SiC), combinations or multiple layers thereof, or the like.

As shown in FIG. 2D, a redistribution layer 32 is disposed on the dielectric layer 31. In some embodiments, the redistribution layer 32 includes a dielectric layer 33 and conductive features 34 and 35 disposed in the dielectric layer 33. Afterwards, a dielectric layer 36 is disposed on the redistribution layer 32 to cover the conductive features 35, thereby forming a semiconductor device 40. In some embodiments, the semiconductor device 40 may be a local silicon interposer (LSI) die. The semiconductor device 40 acts as a bridge to redistribute electrical signals between other semiconductor devices (such as the semiconductor devices 10, 54, and 55 described later) disposed thereon, in accordance with some embodiments.

In some embodiments, the dielectric layers 33 and 36 are formed using a deposition method such as plasma-enhanced chemical vapor deposition (PECVD), low-pressure chemical vapor deposition (LPCVD), or the like. In some embodiments, the dielectric layers 33 and 36 may be made of a polymer material such as epoxy, polyimide, polybenzoxazole (PBO), benzocyclobutene (BCB), solder resist (SR), ABF film, and the like, in accordance with some embodiments. In some embodiments, the dielectric layers 33 and 36 are made of a photosensitive material and may undergo chemical reactions when exposed to light. In some embodiments, the dielectric layers 33 and 36 may include phospho-silicate glass (PSG), boro-silicate glass (BSG), boron-doped phospho-silicate glass (BPSG), undoped silicate glass (USG), or the like. In some embodiments of the present disclosure, the dielectric layers 33 and 36 may include an inorganic dielectric material, which may include a material selected from silicon nitride (SiNₓ), silicon oxide (SiO₂), silicon oxy-nitride (SiONₓ), silicon oxy-carbide (SiOCₓ), silicon carbide (SiC), combinations or multiple layers thereof, or the like.

In some embodiments, the conductive features 34 may include conductive wires, vias, pillars, pads, etc. The conductive features 34 may be formed by a deposition method, such as chemical vapor deposition (CVD), physical vapor deposition (PVD), or atomic layer deposition (ALD), following by a patterning process. The conductive features 34 may include Tungsten (W), aluminum (Al), copper (Cu), titanium (Ti), tantalum (Ta), titanium nitride (TiN), tantalum nitride (TaN), alloys or multiple layers thereof, or the like. The conductive feature 35 may be conductive bumps (e.g., C4 bumps, ball grid arrays, microbumps, etc.) or conductive features utilizing materials such as solder and copper.

The semiconductor device 40 is then placed on a tape layer 37 having a frame 38 for subsequent processes. The tape layer 37 is made of a polymer material or another suitable material, in accordance with some embodiments. In some embodiments, the tape layer 37 include photosensitive or heat-sensitive material and is easily detached from the semiconductor device 40. In some embodiments, the frame 38 protects the semiconductor device 40 from damage during transportation and handling, such as scratches and contamination. Furthermore, the frame 38 provides a stable platform for inspection and testing, and enables the accurate alignment of the semiconductor device 40 during subsequent processes. In some embodiments, the frame 38 includes rigid material provide mechanical support.

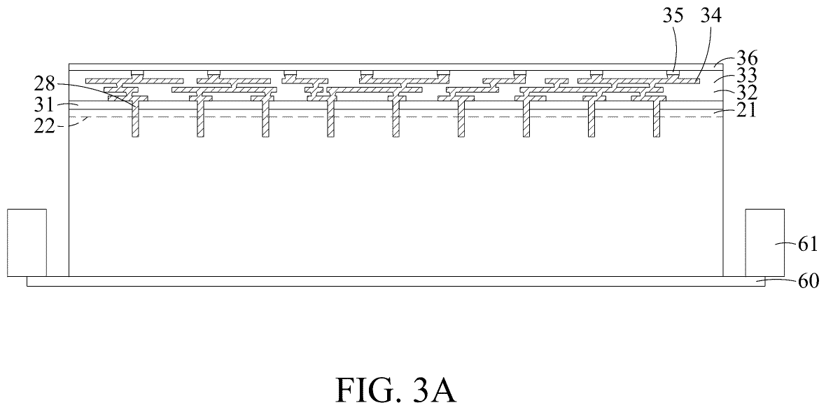

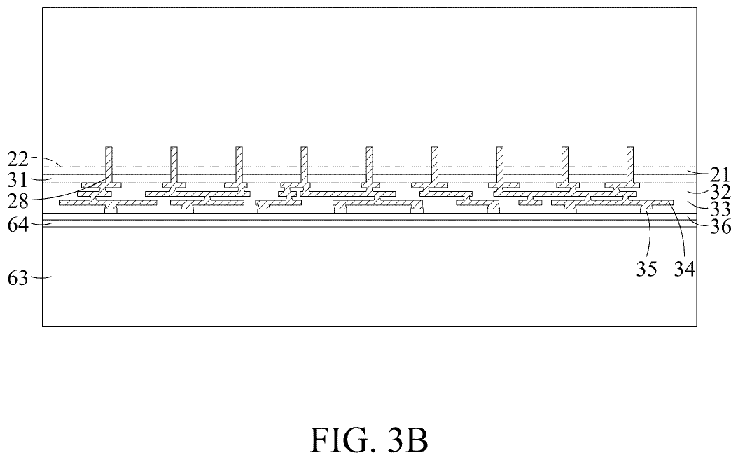

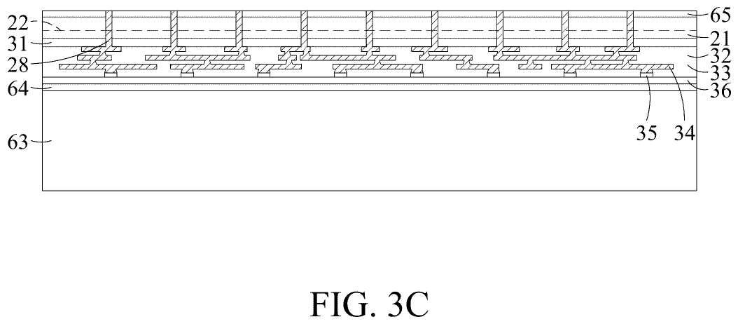

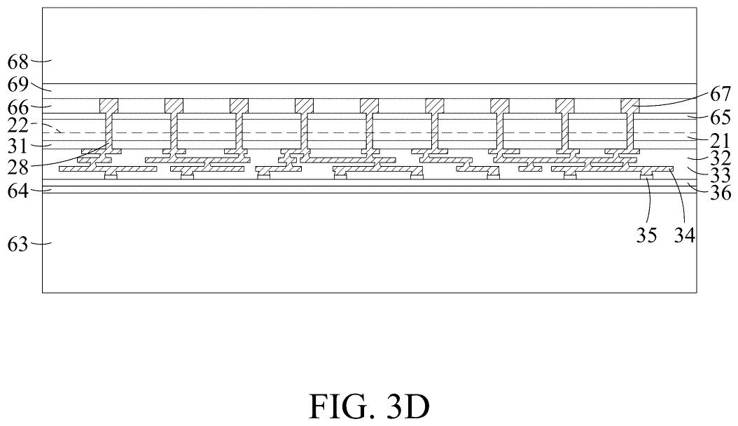

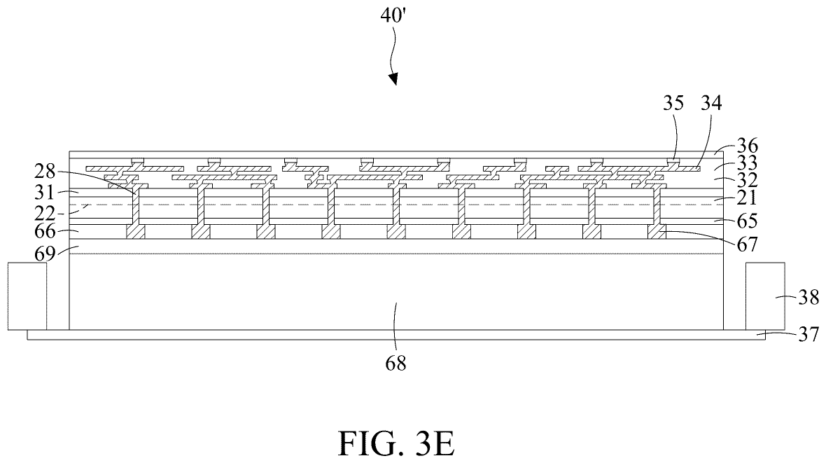

FIG. 3A to FIG. 3E are schematic views showing the process of forming a semiconductor device 40′, in accordance with some embodiments of the present disclosure. As shown in FIG. 3A, a substrate 21 with a device layer 22, conductive features 28, a dielectric layer 31, a redistribution layer 32, and a dielectric layer 36 disposed thereon is provided over a tape layer 60 having a frame 61. Similar elements with same reference number are not describe again for simplicity.

In some embodiments, the tape layer 60 is made of a polymer material or another suitable material, in accordance with some embodiments. In some embodiments, the tape layer 60 include photosensitive or heat-sensitive material and is easily detached from the substrate 21. In some embodiments, the frame 61 protects the structure disposed over the tape layer 60 from damage during transportation and handling, such as scratches and contamination. Furthermore, the frame 61 provides a stable platform for inspection and testing, and enables the accurate alignment of the structure disposed over the tape layer 60 during subsequent processes. In some embodiments, the frame 61 includes rigid material provide mechanical support.

As shown in FIG. 3B, the entire structure is flipped over and disposed over a carrier 63 with an adhesive layer 64 disposed on the carrier 63. Afterwards, the tape layer 60 and the frame 61 are removed. In some embodiments, the carrier 63 may be made of silicon (Si) or other semiconductor materials, such as germanium (Ge) or silicon germanium (SiGe). In some embodiments, the carrier 63 may include a compound semiconductor, such as silicon carbide (SiC), silicon phosphide (SiP), gallium arsenide (GaAs), gallium phosphide (GaP), indium phosphide (InP), indium arsenide (InAs), indium antimonide (InSb), zinc oxide (ZnO), zinc selenide (ZnSe), zinc sulfide (ZnS), zinc telluride (ZnTe), cadmium selenide (CdSe), cadmium sulfide (CdS), and/or cadmium telluride (CdTe); an alloy semiconductor, such as silicon germanium (SiGe), silicon phosphorus carbide (SiPC), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); other group III-V materials; other group II-V materials; or combinations thereof. In some embodiments, the carrier 63 may be a glass substrate or any other substrate material. In some embodiments, the adhesive layer 64 includes glue or other adhesive materials.

In FIG. 3C, the substrate 21 is thinned to expose the conductive features 28 from the substrate 21. Afterwards, a dielectric layer 65 is disposed on the substrate 21. In some embodiments, the dielectric layer 65 is formed using a deposition method such as plasma-enhanced chemical vapor deposition (PECVD), low-pressure chemical vapor deposition (LPCVD), or the like. In some embodiments, the dielectric layer 65 may be made of a polymer material such as epoxy, polyimide, polybenzoxazole (PBO), benzocyclobutene (BCB), solder resist (SR), ABF film, and the like, in accordance with some embodiments. In some embodiments, the dielectric layer 65 is made of a photosensitive material and may undergo chemical reactions when exposed to light. In some embodiments, the dielectric layer 65 may include phospho-silicate glass (PSG), boro-silicate glass (BSG), boron-doped phospho-silicate glass (BPSG), undoped silicate glass (USG), or the like. In some embodiments of the present disclosure, the dielectric layer 65 may include an inorganic dielectric material, which may include a material selected from silicon nitride (SiNₓ), silicon oxide (SiO₂), silicon oxy-nitride (SiONₓ), silicon oxy-carbide (SiOCₓ), silicon carbide (SiC), combinations or multiple layers thereof, or the like. A planarization process, such as chemical mechanical polishing (CMP) or a mechanical grinding process, may then be performed to the dielectric layer 65 to achieve a substantially flat top surface, in accordance with some embodiments.

As shown in FIG. 3D, a dielectric layer 66 having conductive features 67 disposed therein are formed over the dielectric layer 65. In some embodiments, the dielectric layer 65 is formed using a deposition method such as plasma-enhanced chemical vapor deposition (PECVD), low-pressure chemical vapor deposition (LPCVD), or the like. In some embodiments, the dielectric layer 66 may be made of a polymer material such as epoxy, polyimide, polybenzoxazole (PBO), benzocyclobutene (BCB), solder resist (SR), ABF film, and the like, in accordance with some embodiments. In some embodiments, the dielectric layer 66 is made of a photosensitive material and may undergo chemical reactions when exposed to light. In some embodiments, the dielectric layer 66 may include phospho-silicate glass (PSG), boro-silicate glass (BSG), boron-doped phospho-silicate glass (BPSG), undoped silicate glass (USG), or the like. In some embodiments of the present disclosure, the dielectric layer 66 may include an inorganic dielectric material, which may include a material selected from silicon nitride (SiNₓ), silicon oxide (SiO₂), silicon oxy-nitride (SiONₓ), silicon oxy-carbide (SiOCₓ), silicon carbide (SiC), combinations or multiple layers thereof, or the like.

In some embodiments, conductive features 67 may be formed in the dielectric layer 66, and the conductive features 67 include conductive wires, vias, pillars, pads, etc. In some embodiments, the conductive pad 24 and the conductive features 26 and 28 may be formed by a deposition method, such as chemical vapor deposition (CVD), physical vapor deposition (PVD), or atomic layer deposition (ALD), following by a patterning process. The conductive pad 24 and the conductive features 26 and 28 may include Tungsten (W), aluminum (Al), copper (Cu), titanium (Ti), tantalum (Ta), titanium nitride (TiN), tantalum nitride (TaN), alloys or multiple layers thereof, or the like. In some embodiments, the conductive features 67 may be electrically connected to the conductive features 28.

A carrier 68 having a release layer 69 is provided over the dielectric layer 66 and the conductive features 67. The carrier 68 may be made of silicon (Si) or other semiconductor materials, such as germanium (Ge) or silicon germanium (SiGe). In some embodiments, the carrier 68 may include a compound semiconductor, such as silicon carbide (SiC), silicon phosphide (SiP), gallium arsenide (GaAs), gallium phosphide (GaP), indium phosphide (InP), indium arsenide (InAs), indium antimonide (InSb), zinc oxide (ZnO), zinc selenide (ZnSe), zinc sulfide (ZnS), zinc telluride (ZnTe), cadmium selenide (CdSe), cadmium sulfide (CdS), and/or cadmium telluride (CdTe); an alloy semiconductor, such as silicon germanium (SiGe), silicon phosphorus carbide (SiPC), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); other group III-V materials; other group II-V materials; or combinations thereof. In some embodiments, the carrier 68 may be a glass substrate or any other substrate material.

In some embodiments, the release layer 69 may be formed of a polymer-based material and/or an epoxy-based thermal-release material (such as a Light-To-Heat-Conversion (LTHC) material), which is capable of being decomposed under radiation such as a laser beam, so that the carrier 68 may be de-bonded from the overlying structures that will be formed in subsequent processes. In accordance with some embodiments of the present disclosure, the release layer 69 is applied on the carrier 68 through coating.

As shown in FIG. 3E, the carrier 68 is disposed on a tape layer 37 with a frame 38, and then the carrier 63 is removed (debonded) from the dielectric layer 36 by removing the adhesive layer 64, such as by grinding or heating, in accordance with some embodiments. Therefore, the semiconductor device 40′ is formed, in accordance with some embodiments.

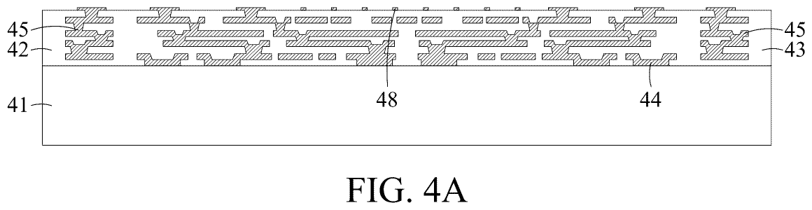

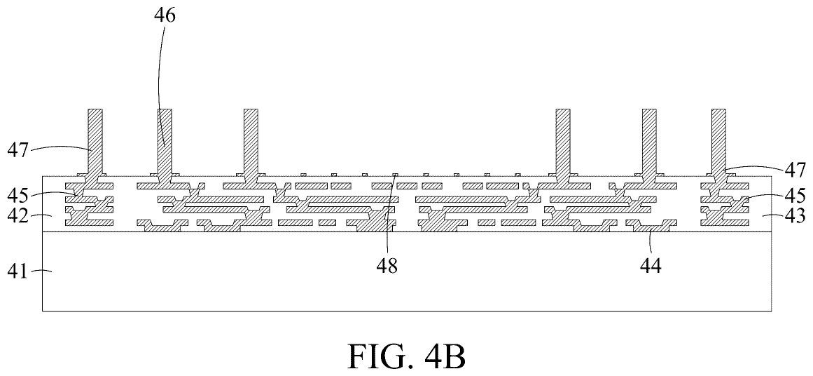

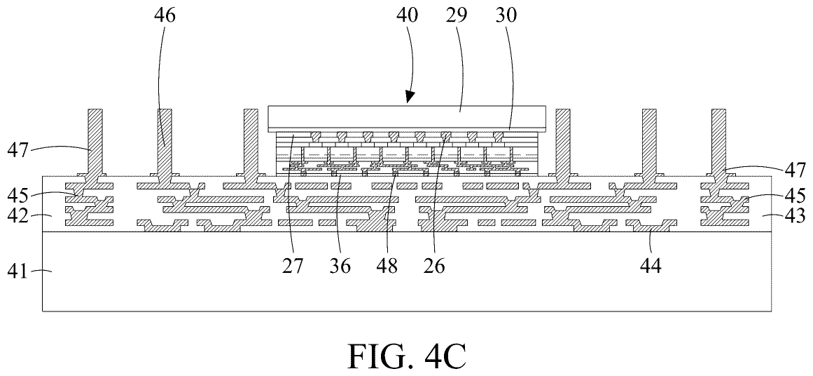

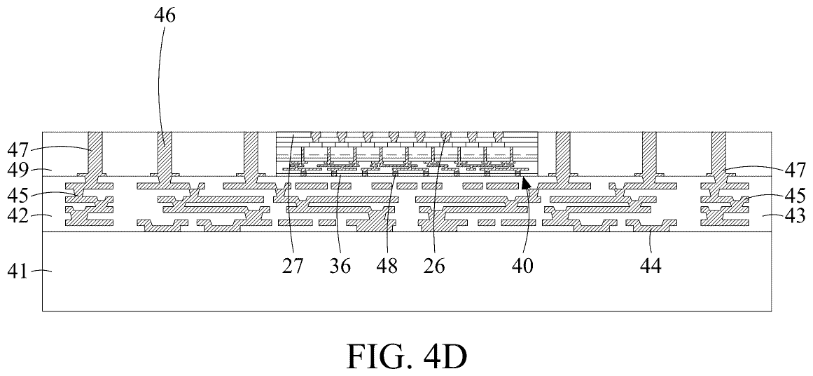

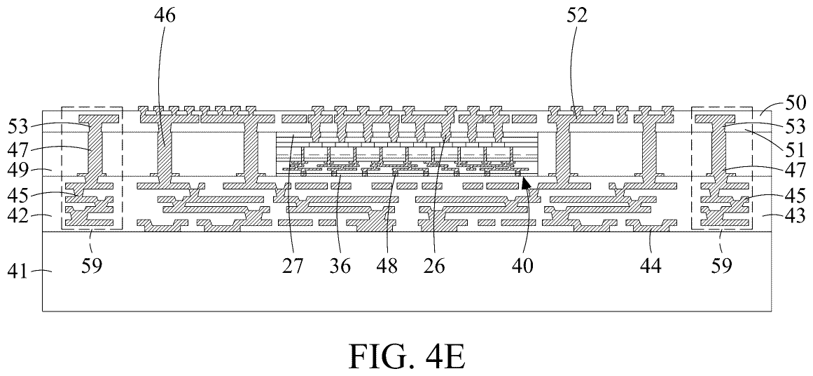

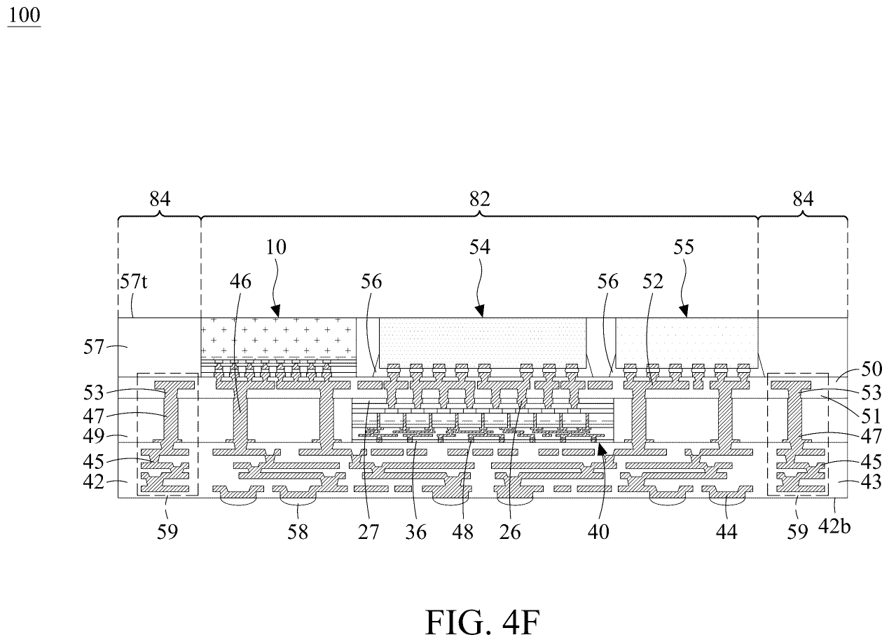

FIG. 4A to FIG. 4F are schematic views showing the process of forming a semiconductor package structure 100, in accordance with some embodiments of the present disclosure. The semiconductor package structure 100 is formed with the semiconductor device 10 in FIG. 1 and the semiconductor device 40 in FIG. 2D or the semiconductor device 40′ in FIG. 3E. As shown in FIG. 4A, a carrier 41 and an interconnect structure 42 (backside RDL) disposed on the carrier 41 are provided in some embodiments. The carrier 41 may be made of silicon (Si) or other semiconductor materials, such as germanium (Ge) or silicon germanium (SiGe). In some embodiments, the carrier 41 may include a compound semiconductor, such as silicon carbide (SiC), silicon phosphide (SiP), gallium arsenide (GaAs), gallium phosphide (GaP), indium phosphide (InP), indium arsenide (InAs), indium antimonide (InSb), zinc oxide (ZnO), zinc selenide (ZnSe), zinc sulfide (ZnS), zinc telluride (ZnTe), cadmium selenide (CdSe), cadmium sulfide (CdS), and/or cadmium telluride (CdTe); an alloy semiconductor, such as silicon germanium (SiGe), silicon phosphorus carbide (SiPC), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); other group III-V materials; other group II-V materials; or combinations thereof. In some embodiments, the carrier 41 may be a glass substrate or any other substrate material.

In some embodiments, the interconnect structure 42 may include a dielectric layer 43, conductive features 44 disposed in the dielectric layer 43, and sealing feature 45 (first sealing feature) disposed in the dielectric layer 43. In some embodiments, the interconnect structure 42 has a height between about 50 um and about 100 um. In some embodiments, the sealing feature 45 has a width between about 50 um and about 150 um. In some embodiments, the dielectric layer 43 is formed using a deposition method such as plasma-enhanced chemical vapor deposition (PECVD), low-pressure chemical vapor deposition (LPCVD), or the like. Afterwards, a planarization process, such as chemical mechanical polishing (CMP) or a mechanical grinding process, may be performed to the dielectric layer 43. In some embodiments, the dielectric layer 43 may be made of a polymer material such as epoxy, polyimide, polybenzoxazole (PBO), benzocyclobutene (BCB), solder resist (SR), ABF film, and the like, in accordance with some embodiments. In some embodiments, the dielectric layer 43 is made of a photosensitive material and may undergo chemical reactions when exposed to light. In some embodiments, the dielectric layer 43 may include phospho-silicate glass (PSG), boro-silicate glass (BSG), boron-doped phospho-silicate glass (BPSG), undoped silicate glass (USG), or the like. In some embodiments of the present disclosure, the dielectric layer 43 may include an inorganic dielectric material, which may include a material selected from silicon nitride (SiNₓ), silicon oxide (SiO₂), silicon oxy-nitride (SiONₓ), silicon oxy-carbide (SiOCₓ), silicon carbide (SiC), combinations or multiple layers thereof, or the like.

The conductive features 44 and the sealing feature 45 are electrically isolated from each other. In some embodiments, the conductive features 44 and the sealing feature 45 may include conductive wires, vias, pillars, etc. The conductive features 44 and the sealing feature 45 may be formed by a deposition method, such as chemical vapor deposition (CVD), physical vapor deposition (PVD), or atomic layer deposition (ALD), following by a patterning process. The conductive features 44 and the sealing feature 45 may include Tungsten (W), aluminum (Al), copper (Cu), titanium (Ti), tantalum (Ta), titanium nitride (TiN), tantalum nitride (TaN), alloys or multiple layers thereof, or the like.

As shown in FIG. 4B, conductive features 46, sealing features 47 (second sealing feature), and conductive features 48 are formed over the interconnect structure 42, in accordance with some embodiments. In some embodiments, the conductive features 46 and the conductive features 48 are physically and electrically connected to the conductive features 44, and the sealing features 47 are connected to the sealing feature 45. In some embodiments, the conductive features 46 and the sealing features 47 may be pillars, such as the conductive feature 46 may be referred to as a first pillar, and the sealing feature 47 may be referred to as a second pillar, but they are not limited thereto. Other configurations, such as wires, pads, or vias may also be included. In some embodiments, the conductive features 46 and the sealing features 47 have a substantially identical height which is higher than the conductive features 48. In some embodiments, the conductive features 46, the sealing features 47, and the conductive features 48 may include Tungsten (W), aluminum (Al), copper (Cu), titanium (Ti), tantalum (Ta), titanium nitride (TiN), tantalum nitride (TaN), alloys or multiple layers thereof, or the like.

As shown in FIG. 4C, the semiconductor device 40 (or 40′) is disposed over the interconnect structure 42, with the conductive features 35 connected to the conductive features 48. In some embodiments, the semiconductor device 40 or 40′ is first placed over the conductive features 48, and then pressure is applied to make the conductive features 48 penetrating the dielectric layer 36 to be in contact with the conductive features 35. Therefore, the semiconductor device 40 or 40′ may be connected to the interconnect structure 42 without using additional underfill material, which not only simplifies the process but also reduces the cost. In some embodiments, the height of the semiconductor device 40 is greater than the height of the conductive feature 46 and the height of the sealing feature 47.

In FIG. 4D, the carrier 29 is thinned by a planarization process, such as chemical mechanical polishing (CMP) or a mechanical grinding process. Afterwards, a molding layer 49 is provided to surround. The molding layer 49, the semiconductor device 40, the conductive feature 46, and the sealing feature 47 are thinned by a planarization process, such as chemical mechanical polishing (CMP) or a mechanical grinding process, to expose the conductive feature 26 of the semiconductor device 40, the conductive feature 46, and the sealing feature 47 from the molding layer 49. In some embodiments, after the planarization process, the molding layer 49 has a height between about 50 um and about 100 um. In some embodiments, the molding layer 49 may include liquid epoxy, deformable gel, a resin, polyimide, polybenzoxazole (PBO), benzocyclobutene (BCB), a silicone, an acrylate or the like.

In FIG. 4E, a redistribution layer 50 (frontside RDL) is formed over the semiconductor device 40, the conductive feature 46, the sealing feature 47, and the molding layer 49. In some embodiments, the redistribution layer 50 includes a dielectric layer 51, conductive features 52 disposed in the dielectric layer 51, and sealing features 53 (third sealing feature) disposed in the dielectric layer 51. In some embodiments, the conductive features 52 are electrically connected to the semiconductor device 40 through the conductive features 26, and electrically connected to the conductive features 46. Moreover, the conductive features 52 are electrically isolated from the sealing features 53. The sealing features 53 is connected to the sealing feature 47.

In some embodiments, the dielectric layer 51 is formed using a deposition method such as plasma-enhanced chemical vapor deposition (PECVD), low-pressure chemical vapor deposition (LPCVD), or the like. In some embodiments, the dielectric layer 51 may be made of a polymer material such as epoxy, polyimide, polybenzoxazole (PBO), benzocyclobutene (BCB), solder resist (SR), ABF film, and the like, in accordance with some embodiments. In some embodiments, the dielectric layer 51 is made of a photosensitive material and may undergo chemical reactions when exposed to light. In some embodiments, the dielectric layer 51 may include phospho-silicate glass (PSG), boro-silicate glass (BSG), boron-doped phospho-silicate glass (BPSG), undoped silicate glass (USG), or the like. In some embodiments of the present disclosure, the dielectric layer 51 may include an inorganic dielectric material, which may include a material selected from silicon nitride (SiNₓ), silicon oxide (SiO₂), silicon oxy-nitride (SiONₓ), silicon oxy-carbide (SiOCₓ), silicon carbide (SiC), combinations or multiple layers thereof, or the like.

In some embodiments, the conductive features 52 and the sealing features 53 may include conductive wires, vias, pillars, pads, etc. The conductive features 52 and the sealing features 53 may be formed by a deposition method, such as chemical vapor deposition (CVD), physical vapor deposition (PVD), or atomic layer deposition (ALD), following by a patterning process. The conductive features 52 and the sealing features 53 may include Tungsten (W), aluminum (Al), copper (Cu), titanium (Ti), tantalum (Ta), titanium nitride (TiN), tantalum nitride (TaN), alloys or multiple layers thereof, or the like.

In some embodiments, the sealing features 45, the sealing features 47, and the sealing features 53 may be collectively referred to as a sealing structure 59. The sealing structure 59 continuously extends from the interconnect structure 42 through the molding layer 49 to the redistribution layer 50, and surrounds the semiconductor device 40. Therefore, peeling and crack may be prevented from occurring between interconnect structure 42, the molding layer 49, and the redistribution layer 50. In some embodiments, the sealing structure 59 is electrically isolated from the semiconductor devices 10, 40, 54, and 55 and conductive features connected to these devices, thereby preventing short circuit from occurring.

In some embodiments, the sealing structure 59 may be used to isolate the interior of the package from the external environment, preventing moisture or other contaminants from entering, and preventing the package from cracking due to thermal cycling or mechanical stress. Especially, the sealing structure 59 has a sealing feature 47 in the

As shown in FIG. 4F, the semiconductor device 10, a semiconductor device 54, and a semiconductor device 55 are disposed over the redistribution layer 50 and electrically connected to the semiconductor device 40 (or 40′) through the redistribution layer 50. Afterwards, underfill material 56 is provided between the redistribution layer 50 and the semiconductor device 54 and the semiconductor device 55. Molding layer 57 is provided over the redistribution layer 50 to surround the semiconductor devices 10, 54, and 55. A planarization process, such as chemical mechanical polishing (CMP) or a mechanical grinding process, is then performed to expose top surfaces of the semiconductor devices 10, 54, and 55 from a top surface 57t of the molding layer 57. The carrier 41 is then removed to expose the conductive features 44 from a bottom surface 42b of the interconnect structure 42, and then conductive features 58 are formed on the conductive features 44 exposed from the bottom surface 42b, thereby forming the semiconductor package structure 100. In some embodiments, the sealing feature 45 in the dielectric layer 43 is not exposed from the bottom surface 42b of the interconnect structure 42 after the carrier 41 is removed to prevent short circuit.

In some embodiments, the semiconductor devices 10, 54, and 55 are electrically connected to each other through the redistribution 50 and the semiconductor device 40. In some embodiments, the semiconductor devices 10, 54, and 55 are disposed in a die area 82 surrounded by a seal ring area 84. In some embodiments, the sealing structure 59 is disposed in the seal ring area 84. In some embodiments, the semiconductor devices 10, 54, and 55 may have different functionalities. For example, in some embodiments, the semiconductor device 10, 54, and 55 may include logic dies, system-on-chip (SoC) dies, memory dies, radio frequency (RF) dies, input/output (I/O) dies, or other applicable dies. The memory dies may include memory devices such as static random access memory (SRAM) devices, dynamic random access memory (DRAM) devices, other suitable devices, or a combination thereof. In some embodiments, the semiconductor device 10 is a SoC die, the semiconductor device 54 is a memory die which function as high bandwidth memories (HBM), and the semiconductor device 55 is an input/output die.

The underfill material 56 may be configured to provide a stronger mechanical connection and a heat bridge between the redistribution layer 50 and the semiconductor devices 54 and 55, in accordance with some embodiments of the present disclosure. In some embodiments, the underfill material 56 includes liquid epoxy, deformable gel, silicon rubber, or the like. In some embodiments, the molding layer 57 may include liquid epoxy, deformable gel, a resin, polyimide, polybenzoxazole (PBO), benzocyclobutene (BCB), a silicone, an acrylate or the like. The conductive feature 58 may be conductive bumps (e.g., C4 bumps, ball grid arrays, microbumps, etc.) or conductive features utilizing materials such as solder and copper.

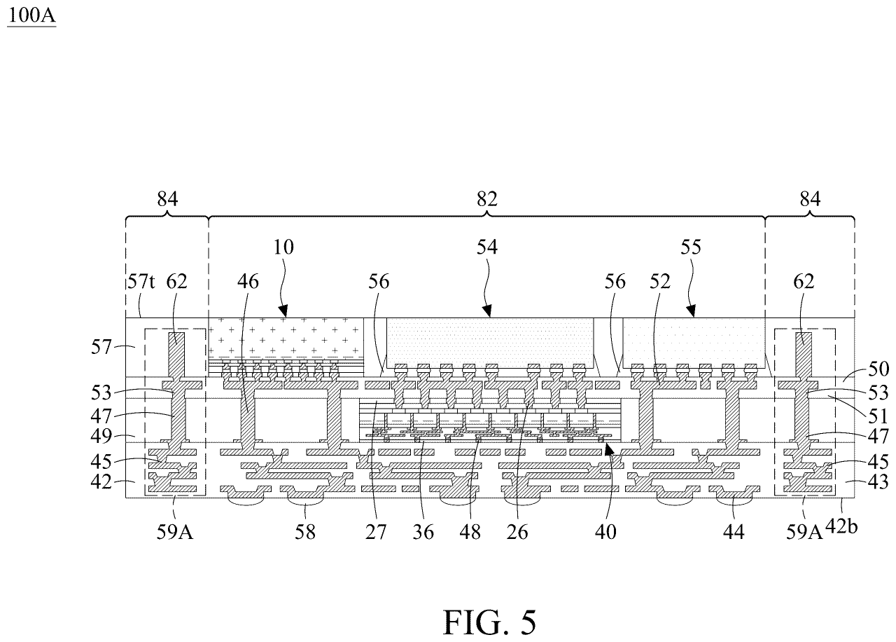

FIG. 5 is a cross-sectional view of a semiconductor package structure 100A, in accordance with some embodiments of the present disclosure. As shown in FIG. 5, the difference between the semiconductor package structures 100A and 100A is that the semiconductor package structure 100A has a sealing structure 59A including the sealing features 45, the sealing features 47, the sealing features 53, and sealing features 62 (fourth sealing feature). The sealing features 62 are connected to the sealing features 53 and extend into the molding layer 57. Therefore, the sealing structure 59A continuously extends from the interconnect structure 42 through the molding layer 49 and the redistribution layer 50 to the molding layer 57. In some embodiments, the sealing feature 62 of the sealing structure 59A does not expose from the top surface 57t of the molding layer 57 to prevent short circuit. In some embodiments, the sealing features 62 may be pillars, but they are not limited thereto. Other configurations, such as wires, pads, or vias may also be included. In some embodiments, a height of the sealing feature 62 is less than a height of at least one of the semiconductor devices 10, 54, and 55.

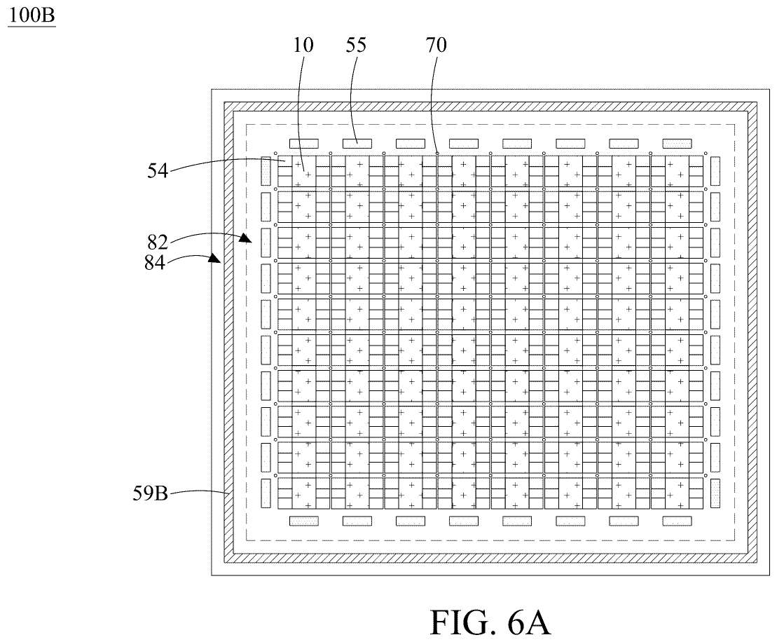

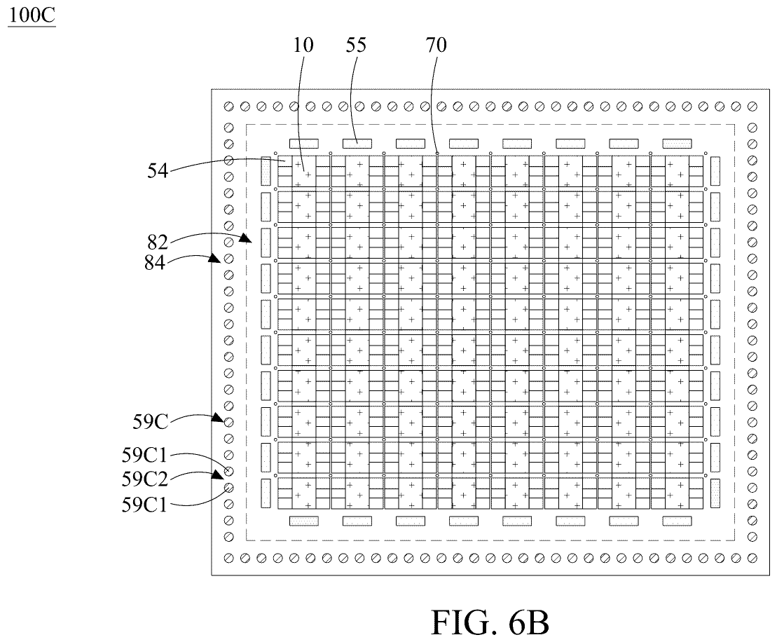

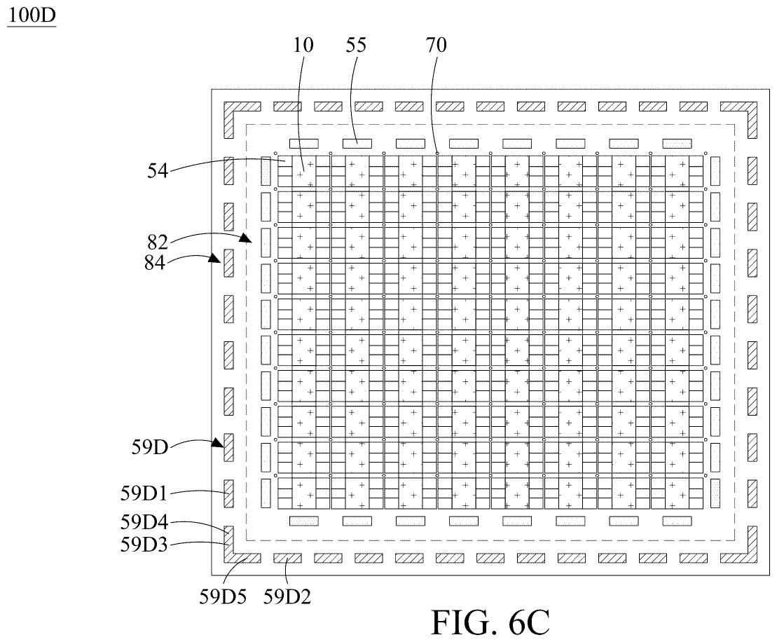

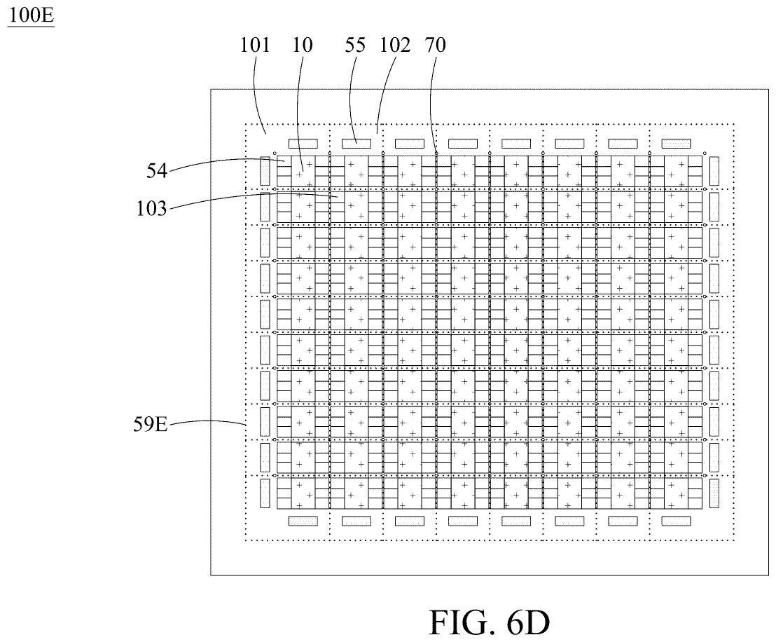

FIG. 6A, FIG. 6B, FIG. 6C, and FIG. 6D are top views of semiconductor package structures 100B, 100C, 100D, and 100E, respectively, in accordance with some embodiments of the present disclosure. To ensure clarity regarding the relationship between the cross-sectional views shown in FIG. 4F and FIG. 5 and the top views shown in FIG. 6A to FIG. 6D, each of the cross-sectional configurations in FIG. 4F and FIG. 5 is applicable to and may be implemented in combination with any of the top view configurations in FIG. 6A to FIG. 6D. Specifically, the cross-sectional configuration of the semiconductor package structure 100 can be applied in conjunction with any of the top view configurations (semiconductor package structures 100B, 100C, 100D, or 100E). Likewise, the cross-sectional configuration of the semiconductor package structure 100A can also be applied in conjunction with any of the top view configurations (semiconductor package structures 100B, 100C, 100D, or 100E). Elements shown in semiconductor package structures 100 or 100A are similar to, or the same as, elements shown in semiconductor package structures 100B, 100C, 100D, or 100E. This combinability allows for flexible implementation, and any reference to a specific top view (semiconductor package structure 100B, 100C, 100D, or 100E) should be understood as being applicable to both cross-sectional configurations (semiconductor package structure 100 and 100A), unless explicitly stated otherwise. By establishing this correspondence, the descriptions of the various embodiments avoid unnecessary repetition while ensuring that the technical scope of the disclosure is clearly defined.

As shown in FIG. 6A, the semiconductor package structure 100B includes a sealing structure 59B surrounding the semiconductor devices 10, 54, and 55, in accordance with some embodiments. In some embodiments, the semiconductor devices 10, 54, and 55 are disposed in the die area 82, and the sealing structure 59B is disposed in the seal ring area 84. The die area 82 is adjacent to the seal ring area 84 and surrounded by the seal ring area 84, in accordance with some embodiments. In some embodiments, the sealing structure 59B has a continuous structure and continuously surrounds the semiconductor devices 10, 54, and 55. In some embodiments, through holes 70 (not shown in FIG. 4F and FIG. 5) are provided in the die area 82 and extend across the interconnect structure 42, the molding layer 49, the redistribution layer 50, and the molding layer 57 for subsequent processes.

In FIG. 6B, the semiconductor package structure 100C includes a sealing structure 59C surrounding the semiconductor devices 10, 54, and 55, in accordance with some embodiments. The sealing structure 59C is disposed in the seal ring area 84 and have a plurality of segments 59C1. In some embodiments, the segments 59C1 are separated from each other and surrounds the die area 82, and a gap 59C2 is between two adjacent segments 59C1. In some embodiments, each of the segments 59C1 has a circular shape in the top view, but they are not limited thereto. In some embodiments, the segments 59C1 may have other shapes as well.

In FIG. 6C, the semiconductor package structure 100D includes a sealing structure 59D surrounding the semiconductor devices 10, 54, and 55, in accordance with some embodiments. In some embodiments, the sealing structure 59D has segments extending in different directions. For example, a segment 59D1 and a segment 59D2 of the sealing structure 59D are disposed on different sides of the semiconductor package structure 100D and extend in different directions, such as the segment 59D1 may extend in a direction substantially perpendicular to the direction that the segment 59D2 extends. In some embodiments, the sealing structure 59D further includes a segment 59D3 located at a corner of the semiconductor package structure 100D. The segment 59D3 includes a portion 59D 4 extending parallel to the segment 59D1, and a portion 59D5 extending parallel to the segment 59D2.

As shown in FIG. 6D, the semiconductor package structure 100E includes a sealing structure 59E surrounding the semiconductor devices 10, 54, and 55, in accordance with some embodiments. In some embodiments, the sealing structure 59E not only surrounds all of the semiconductor devices 10, 54, and 55, but also extends between the semiconductor devices, such as between two semiconductor devices 10, between two semiconductor devices 54, or between two semiconductor devices 55, to surround some of the semiconductor devices 10, 54, and 55. For example, the semiconductor package structure 100E includes sub-portions 101, 102, and 103. The sub-portion 101 is at a corner of the semiconductor package structure 100E, the sub-portion 102 is at an edge of the semiconductor package structure 100E, and the sub-portion 103 is at the middle of the semiconductor package structure 100E. Each of the sub-portions 101 and 102 includes a semiconductor device 10, a semiconductor device 54, and a semiconductor device 55. The sub-portion 103 includes a semiconductor device 10 and a semiconductor device 54. The sealing structure 59E extends between two semiconductor devices in the top view, such as extends between the sub-portions 101 and 102, and between the sub-portions 102 and 103.

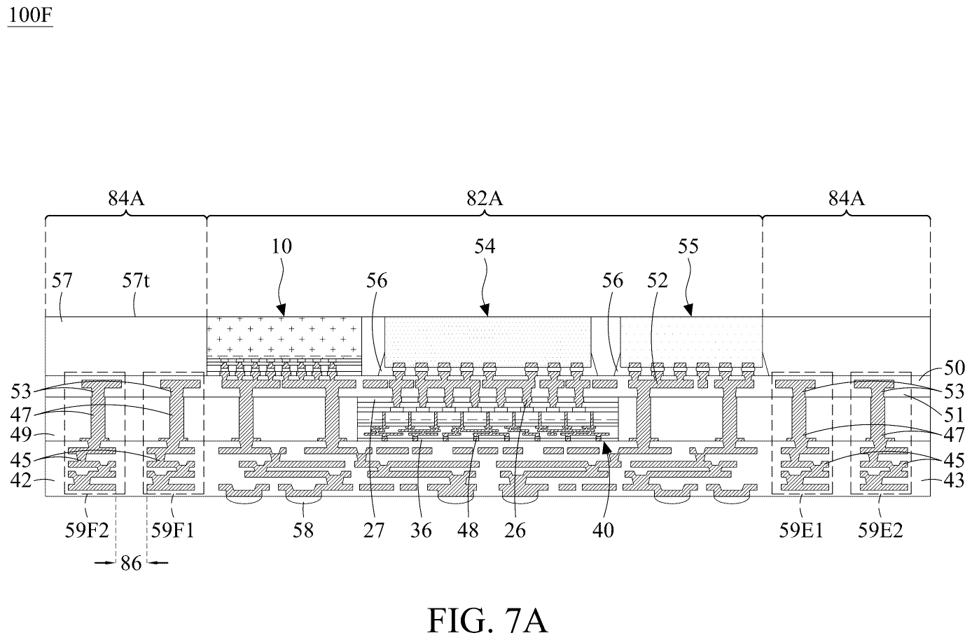

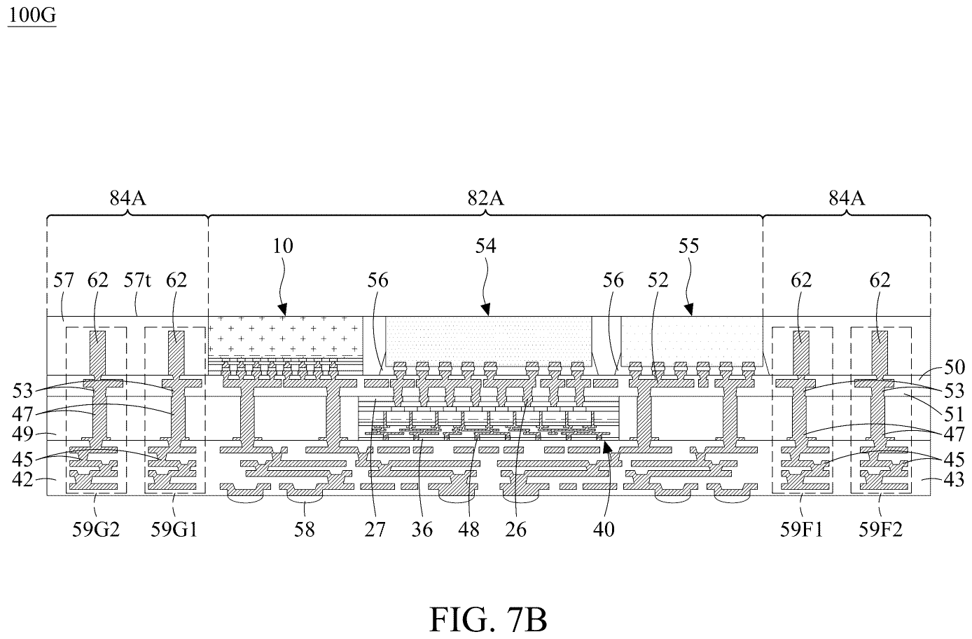

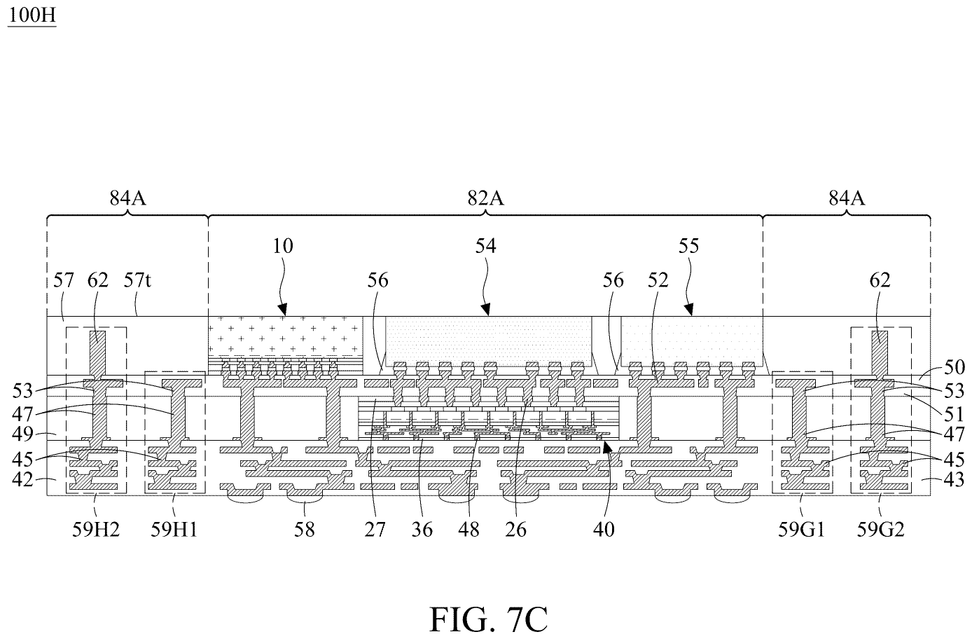

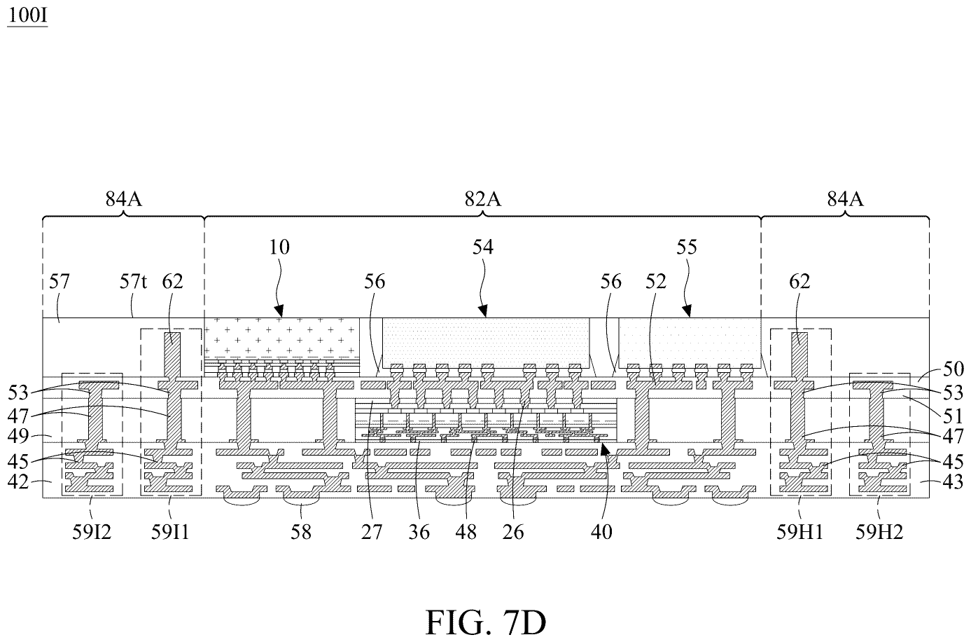

FIG. 7A is a cross-sectional view of a semiconductor package structure 100F in accordance with some embodiments of the present disclosure. As shown in FIG. 7A, the semiconductor package structure 100F includes sealing structures 59F1 and 59F2 in a seal ring area 84A. Semiconductor devices 10, 54, and 55 are disposed in the die area 82A and surrounded by the seal ring area 84A, which means the semiconductor devices 10, 54, and 55 are surrounded by the sealing structures 59F1 and 59F2. In some embodiments, the sealing structure 59F1 is surrounded by the sealing structure 59F2. In some embodiments, each of the sealing structures 59F1 and 59F2 extends from the interconnect structure 42 through the molding layer 49 to the redistribution layer 50. In some embodiments, the sealing structures 59F1 and 59F2 are spaced apart from the molding layer 57. In some embodiments, the sealing structures 59F1 and 59F2 are spaced apart from each other and has a distance 86 between the sealing structures 59F1 and 59F2. The distance 86 may be defined as the lowest number of the distance between two closest sealing features 45, the distance between two closest sealing features 47, and the distance between two closest sealing features 53. In some embodiments, the distance 86 is between about 10 um and about 50 um.

FIG. 7B is a cross-sectional view of a semiconductor package structure 100G in accordance with some embodiments of the present disclosure. As shown in FIG. 7B, the semiconductor package structure 100G includes sealing structures 59G1 and 59G2 in the seal ring area 84A. In some embodiments, the sealing structure 59G1 is surrounded by the sealing structure 59G2. In some embodiments, each of the sealing structures 59G1 and 59G2 has a sealing feature 62 extending into the molding layer 57, resulting the sealing structures 59G1 and 59G2 extending from the interconnect structure 42 through the molding layer 49 and the redistribution layer 50 to the molding layer 57.

FIG. 7C is a cross-sectional view of a semiconductor package structure 100H in accordance with some embodiments of the present disclosure. As shown in FIG. 7C, the semiconductor package structure 100H includes sealing structures 59H1 and 59H2 in the seal ring area 84A. In some embodiments, the sealing structure 59H1 is surrounded by the sealing structure 59H2. In some embodiments, the sealing structures 59H2 has a sealing feature 62 extending into the molding layer 57, resulting the sealing structure 59H2 extending from the interconnect structure 42 through the molding layer 49 and the redistribution layer 50 to the molding layer 57. The sealing structure 59H1 extends from the interconnect structure 42 through the molding layer 49 to the redistribution layer 50, and it is spaced apart from the molding layer 57.

FIG. 7D is a cross-sectional view of a semiconductor package structure 100I in accordance with some embodiments of the present disclosure. As shown in FIG. 7D, the semiconductor package structure 100I includes sealing structures 59I1 and 59I2 in the seal ring area 84A. In some embodiments, the sealing structure 59I1 is surrounded by the sealing structure 59I2. In some embodiments, the sealing structures 59I1 has a sealing feature 62 extending into the molding layer 57, resulting the sealing structure 59I1 extending from the interconnect structure 42 through the molding layer 49 and the redistribution layer 50 to the molding layer 57. The sealing structure 59I2 extends from the interconnect structure 42 through the molding layer 49 to the redistribution layer 50, and it is spaced apart from the molding layer 57.

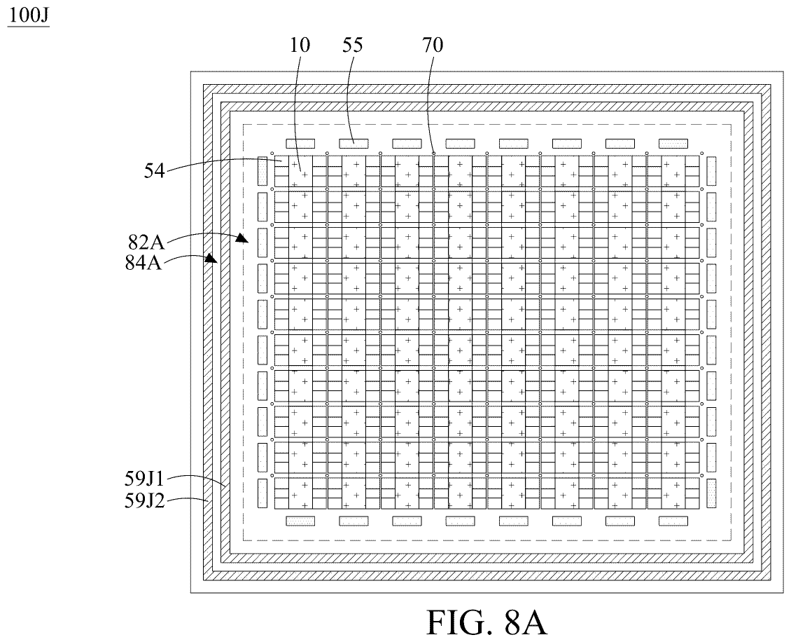

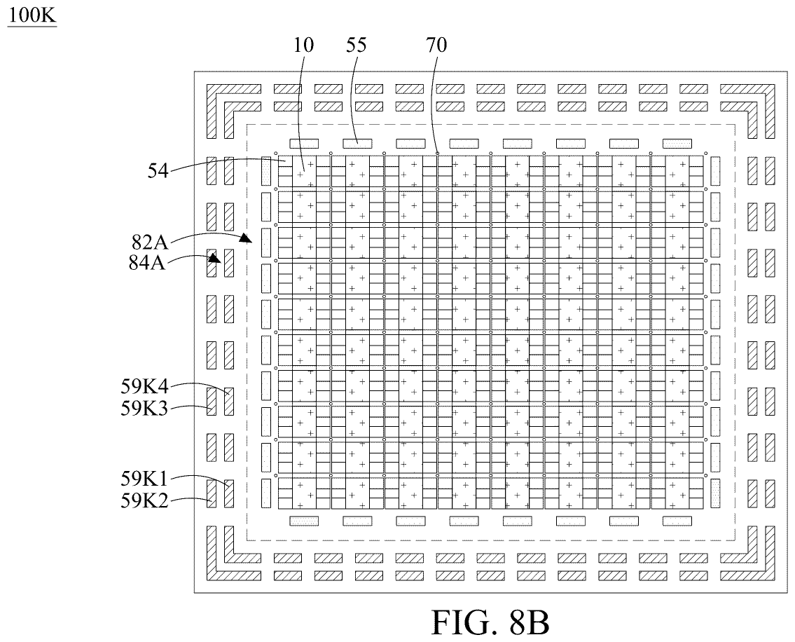

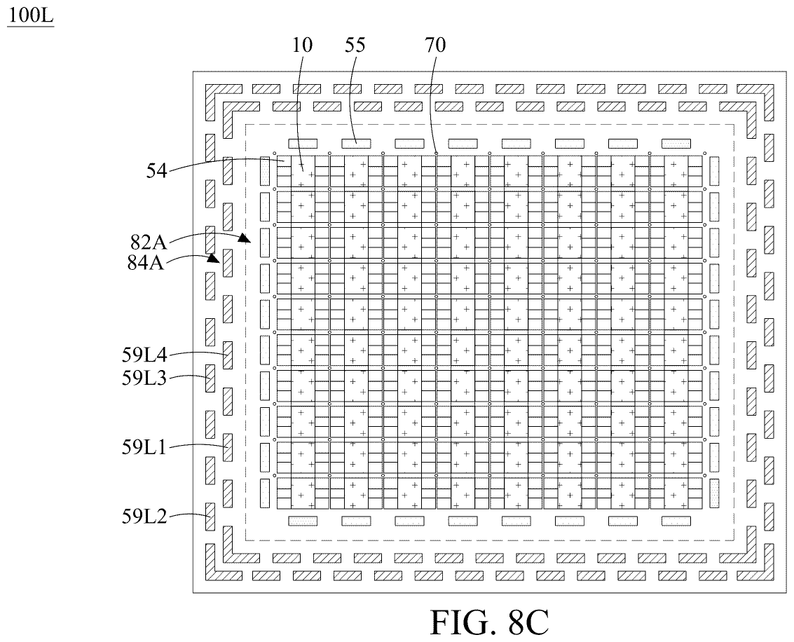

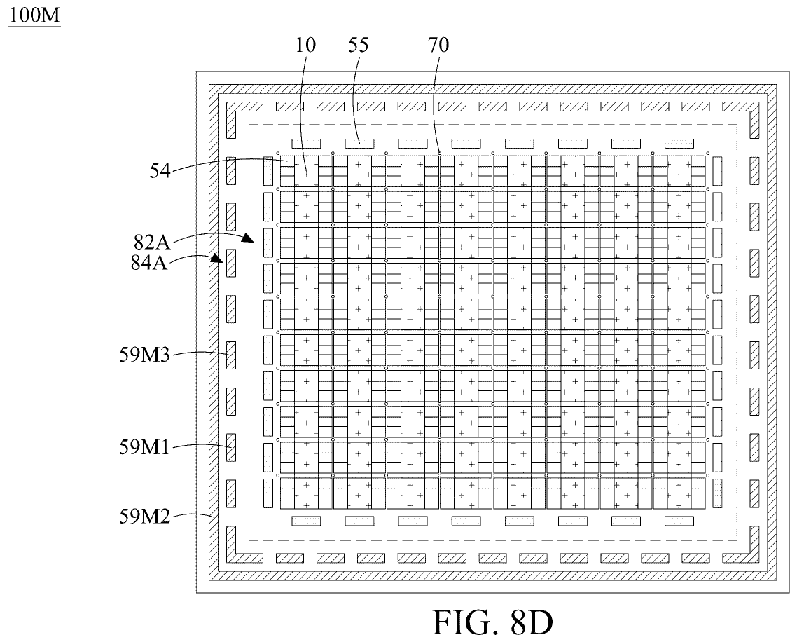

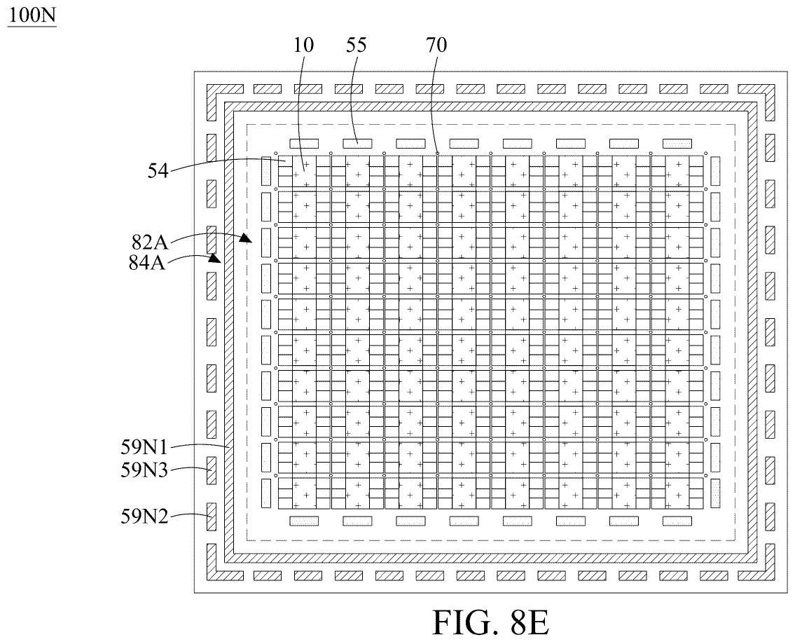

FIG. 8A, FIG. 8B, FIG. 8C, FIG. 8D, and FIG. 8E are top views of semiconductor package structures 100J, 100K, 100L, 100M, and 100N, respectively, in accordance with some embodiments of the present disclosure. To ensure clarity regarding the relationship between the cross-sectional views shown in FIG. 7A to FIG. 7D and the top views shown in FIG. 8A to FIG. 8E, each of the cross-sectional configurations in FIG. 7A to FIG. 7D is applicable to and may be implemented in combination with any of the top view configurations in FIG. 8A to FIG. 8E. Elements shown in semiconductor package structures 100F, 100G, 100H, or 100I are similar to, or the same as, elements shown in semiconductor package structures 100J, 100K, 100L, 100M, or 100N. This Combinability allows for flexible implementation, and any reference to a specific top view (semiconductor package structure 100J, 100K, 100L, 100M, or 100N) should be understood as being applicable to the cross-sectional configurations (semiconductor package structures 100F, 100G, 100H, or 100I), unless explicitly stated otherwise. By establishing this correspondence, the descriptions of the various embodiments avoid unnecessary repetition while ensuring that the technical scope of the disclosure is clearly defined.

As shown in FIG. 8A, the semiconductor package structure 100J has sealing structures 59J1 and 59J2 disposed in the seal ring area 84A, in accordance with some embodiments. It should be noted that the sealing structure 59J1 in the top view may correspond to the sealing structures 59F1, 59G1, 59H1, or 59I1 in the cross-sectional views in FIG. 7A to 7D, and the sealing structure 59J2 in the top view may correspond to the sealing structures 59F2, 59G2, 59H2, or 59I2 in the cross-sectional views in FIG. 7A to FIG. 7D. The sealing structures 59J1 and 59J2 surround the semiconductor devices 10, 54, and 55, in accordance with some embodiments. In some embodiments, each of the sealing structures 59J1 and 59J2 has a continuous structure and continuously surrounds the semiconductor devices 10, 54, and 55. In some embodiments, the sealing structure 59J1 is surrounded by the sealing structure 59J2.

As shown in FIG. 8B, the semiconductor package structure 100K has sealing structures 59K1 and 59K2 disposed in the seal ring area 84A, in accordance with some embodiments. It should be noted that the sealing structure 59K1 in the top view may correspond to the sealing structures 59F1, 59G1, 59H1, or 59I1 in the cross-sectional views in FIG. 7A to 7D, and the sealing structure 59K2 in the top view may correspond to the sealing structures 59F2, 59G2, 59H2, or 59I2 in the cross-sectional views in FIG. 7A to FIG. 7D. The sealing structures 59K1 and 59K2 surround the semiconductor devices 10, 54, and 55, in accordance with some embodiments. In some embodiments, the sealing structure 59K1 has segments 59K3 separated from each other, and the sealing structure 59K2 has segments 59K4 separated from each other. In some embodiments, each of the segments 59K3 and each of the segments 59K4 are arranged in a one-to-one arrangement. The corresponding segments 59K3 and 59K4 are positioned such that the start and end points of each segment 59K3 correspond to the start and end points of the respective segment 59K4.

As shown in FIG. 8C, the semiconductor package structure 100L has sealing structures 59L1 and 59L2 disposed in the seal ring area 84A, in accordance with some embodiments. It should be noted that the sealing structure 59L1 in the top view may correspond to the sealing structures 59F1, 59G1, 59H1, or 59I1 in the cross-sectional views in FIG. 7A to 7D, and the sealing structure 59L2 in the top view may correspond to the sealing structures 59F2, 59G2, 59H2, or 59I2 in the cross-sectional views in FIG. 7A to FIG. 7D. The sealing structures 59L1 and 59L2 surround the semiconductor devices 10, 54, and 55, in accordance with some embodiments. In some embodiments, the sealing structure 59L1 has segments 59L3 separated from each other, and the sealing structure 59L2 has segments 59L4 separated from each other. In some embodiments, each of the segments 59L3 and each of the segments 59L4 are arranged in a staggered arrangement, wherein the corresponding segments 59L3 and 59L4 are shifted by a specific distance or interval.

As shown in FIG. 8D, the semiconductor package structure 100M has sealing structures 59M1 and 59M2 disposed in the seal ring area 84A, in accordance with some embodiments. It should be noted that the sealing structure 59M1 in the top view may correspond to the sealing structures 59F1, 59G1, 59H1, or 59I1 in the cross-sectional views in FIG. 7A to 7D, and the sealing structure 59M2 in the top view may correspond to the sealing structures 59F2, 59G2, 59H2, or 59I2 in the cross-sectional views in FIG. 7A to FIG. 7D. The sealing structures 59M1 and 59M2 surround the semiconductor devices 10, 54, and 55, in accordance with some embodiments. In some embodiments, the sealing structure 59M1 has segments 59M3 separated from each other, and the sealing structure 59M2 continuously surrounds the sealing structure 59M1.

As shown in FIG. 8E, the semiconductor package structure 100N has sealing structures 59N1 and 59N2 disposed in the seal ring area 84A, in accordance with some embodiments. It should be noted that the sealing structure 59N1 in the top view may correspond to the sealing structures 59F1, 59G1, 59H1, or 59I1 in the cross-sectional views in FIG. 7A to 7D, and the sealing structure 59N2 in the top view may correspond to the sealing structures 59F2, 59G2, 59H2, or 59I2 in the cross-sectional views in FIG. 7A to FIG. 7D. The sealing structures 59N1 and 59N2 surround the semiconductor devices 10, 54, and 55, in accordance with some embodiments. In some embodiments, the sealing structure 59N1 continuously surrounds the die area 82A, and sealing structure 59N2 has segments 59N3 separated from each other and surrounding the sealing structure 59N1.

In summary, a semiconductor package structure having a seal ring extending across the structure is provided in some embodiments of the present disclosure. Such design prevents the penetration of passivation layer peeling and redistribution layer cracking into the active area. This design ensures enhanced structural integrity and improves device reliability.

A semiconductor package structure is provided in some embodiments of the present disclosure. The semiconductor package includes an interconnect structure, a first molding layer disposed over the interconnect structure, a first semiconductor die disposed in the first molding layer, a redistribution layer disposed over the first molding layer, and a first sealing structure extending from the interconnect structure through the first molding layer to the redistribution layer. The first semiconductor die is surrounded by the first sealing structure.

A semiconductor package structure having a die area and a seal ring area surrounding the die area is provided in some embodiments of the present disclosure. The semiconductor package includes an interconnect structure, a molding layer disposed over the interconnect structure, a redistribution layer disposed over the molding layer, a first semiconductor die disposed in the molding layer and in the die area, a conductive feature disposed in the die area and electrically connected to the first semiconductor die, and a first sealing structure disposed in the seal ring area and electrically isolated from the first semiconductor die. The conductive feature extends in the molding layer. The first sealing structure extends in the molding layer.

A method for forming a semiconductor package structure is provided in some embodiments of the present disclosure. The method includes forming a first sealing feature and a first conductive feature in a first dielectric layer, disposing a first semiconductor die over the first sealing feature and electrically connected to the first conductive feature, forming a second sealing feature over the first sealing feature and connecting to the first sealing feature, forming a first molding layer surrounding the first semiconductor die and the second sealing feature, forming a second dielectric layer over the first molding layer, and forming a third sealing feature in the second dielectric layer and connecting to the second sealing feature. The first sealing feature, the second sealing feature, and the third sealing feature are electrically isolated from the first conductive feature.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
an interconnect structure;
a first molding layer disposed over the interconnect structure;
a first semiconductor die disposed in the first molding layer;
a redistribution layer disposed over the first molding layer; and
a first sealing structure extending from the interconnect structure through the first molding layer to the redistribution layer, wherein the first semiconductor die is surrounded by the first sealing structure.

2. The semiconductor package structure as claimed in claim 1, further comprising:
a second semiconductor die disposed over the redistribution layer; and
a second molding layer disposed over the redistribution layer and surrounds the second semiconductor die, wherein the first sealing structure further extends into the second molding layer from the redistribution layer.

3. The semiconductor package structure as claimed in claim 2, further comprising a second sealing structure surrounding the second semiconductor die and separated from the first sealing structure.

4. The semiconductor package structure as claimed in claim 3, wherein the second sealing structure extends from the interconnect structure through the first molding layer to the redistribution layer, and is spaced apart from the second molding layer.

5. The semiconductor package structure as claimed in claim 4, wherein the first sealing structure is surrounded by the second sealing structure.

6. The semiconductor package structure as claimed in claim 4, wherein the second sealing structure is surrounded by the first sealing structure.

7. The semiconductor package structure as claimed in claim 3, wherein the second sealing structure continuously extends from the interconnect structure through the first molding layer and the redistribution layer to the second molding layer.

8. A semiconductor package structure having a die area and a seal ring area surrounding the die area, comprising:
an interconnect structure;
a molding layer disposed over the interconnect structure;
a redistribution layer disposed over the molding layer;
a first semiconductor die disposed in the molding layer and in the die area;
a conductive feature disposed in the die area and electrically connected to the first semiconductor die, wherein the conductive feature extends in the molding layer; and
a first sealing structure disposed in the seal ring area and electrically isolated from the first semiconductor die, wherein the first sealing structure extends in the molding layer.

9. The semiconductor package structure as claimed in claim 8, wherein the first sealing structure comprises a first pillar disposed in the molding layer, and the conductive feature comprises a second pillar disposed in the molding layer.

10. The semiconductor package structure as claimed in claim 8, wherein the first sealing structure comprises a plurality of first segments spaced apart from each other in a top view.

11. The semiconductor package structure as claimed in claim 10, further comprising a second sealing structure disposed in the seal ring area, electrically isolated from the first semiconductor die, and comprises a plurality of second segments spaced apart from each other, wherein the first sealing structure is surrounded by the second sealing structure in the top view.

12. The semiconductor package structure as claimed in claim 11, wherein the first segments and the second segments are arranged in a one-to-one arrangement in the top view.

13. The semiconductor package structure as claimed in claim 11, wherein the first segments and the second segments are arranged in a staggered arrangement in the top view.

14. The semiconductor package structure as claimed in claim 10, further comprising a second sealing structure disposed in the seal ring area, electrically isolated from the first semiconductor die, and continuously surrounding the die area, wherein the first sealing structure is surrounded by the second sealing structure.

15. The semiconductor package structure as claimed in claim 10, further comprising a second sealing structure disposed in the seal ring area, electrically isolated from the first semiconductor die, and continuously surrounding the die area, wherein the second sealing structure is surrounded by the first sealing structure.

16. The semiconductor package structure as claimed in claim 8, further comprising a plurality of second semiconductor dies disposed over the redistribution layer, wherein the first sealing structure extends between two of the plurality of second semiconductor dies in a top view.

17. A method for forming a semiconductor package structure, comprising:
forming a first sealing feature and a first conductive feature in a first dielectric layer;
disposing a first semiconductor die over the first sealing feature and electrically connected to the first conductive feature;
forming a second sealing feature over the first sealing feature and connecting to the first sealing feature;
forming a first molding layer surrounding the first semiconductor die and the second sealing feature;
forming a second dielectric layer over the first molding layer; and
forming a third sealing feature in the second dielectric layer and connecting to the second sealing feature, wherein the first sealing feature, the second sealing feature, and the third sealing feature are electrically isolated from the first conductive feature.

18. The method for forming the semiconductor package structure as claimed in claim 17, further comprising:
forming a fourth sealing feature over the second dielectric layer and connected to the third sealing feature; and
forming a second molding layer surrounding the fourth sealing feature.

19. The method for forming the semiconductor package structure as claimed in claim 18, further comprising disposing a second semiconductor die over the second dielectric layer, wherein the second semiconductor die is electrically isolated from the fourth sealing feature, electrically connected to the first semiconductor die, and surrounded by the second molding layer, and a height of the fourth sealing feature is less than a height of the second semiconductor die.

20. The method for forming the semiconductor package structure as claimed in claim 17, further comprising forming a second conductive feature in the second dielectric layer, wherein the second conductive feature is electrically isolated from the third sealing feature and electrically connected to the first semiconductor die.
